(19) United States
(12) Patent Application Publication
(10) Pub. No.: US 2017/0069793 A1
(43) Pub. Date: Mar. 9, 2017

(54) ULTRAVIOLET LIGHT-EMITTING DEVICE AND PRODUCTION METHOD THEREFOR

(71) Applicant: TOYODA GOSEI CO., LTD., Kiyosu-shi (JP)

(72) Inventor: Yoshiki SAITO, Kiyosu-shi (JP)

(21) Appl. No.: 15/221,430

(22) Filed: Jul. 27, 2016

(30) Foreign Application Priority Data
Sep. 3, 2015 (JP) 2015-173525

(51) Int. Cl. H01L 33/32; H01L 33/62; H01L 33/24; H01L 33/00

(52) U.S. Cl. CPC H01L 33/32; H01L 33/0075; H01L 33/62; H01L 33/24

(57) ABSTRACT

The present invention provides an ultraviolet light-emitting device exhibiting improved crystal quality, flatness, and feasibility of filling in irregularities. The ultraviolet light-emitting device has a substrate having irregularities, an AIN buffer layer formed on the substrate by sputtering, an undoped AlGaN layer, an n-type AlGaN layer, a light-emitting layer, an electron blocking layer made of p-type AlGaN, and a p-type contact layer made of p-type AlGaN, each of the layers sequentially deposited. The Al composition ratio of the undoped layer is the smallest and the Al composition ratio is increased in the order of the undoped layer, the n-type layer, the p-type contact layer, and the electron blocking layer. Thus, the Al composition ratio of the entire device is reduced. As a result, the crystal quality or flatness, and feasibility of filling in irregularities on the substrate are improved.

### BACKGROUND OF THE INVENTION

Field of the Invention

The present invention relates to a Group III nitride semiconductor ultraviolet light-emitting device, and a production method therefor.

Background Art

In the conventional Group III nitride semiconductor ultraviolet light-emitting device, to reduce self-absorption by the material, each layer must be made of a material having large bandgap energy, specifically, 3.39 eV or more at a room temperature, and AlGaN has been mainly used.

Japanese Patent Application Laid-Open (kokai) No. 2013-222746 describes a Group III nitride semiconductor ultraviolet light-emitting device having the following structure. The ultraviolet light-emitting device of Japanese Patent Application Laid-Open (kokai) No. 2013-222746 comprises a crystal nuclei formed in an island-shape on a substrate, a buffer layer formed so as to fill in and cover the crystal nuclei, an n-type layer formed on the buffer layer, a light-emitting layer formed on the n-type layer, an electron blocking layer formed on the light-emitting layer, and a p-type layer formed on the electron blocking layer. Each of these layers is formed of AlGaN or AIN. The Al composition ratio of the n-type layer is lowest, and the Al composition ratios of the buffer layer and the p-type layer are lowest next to the n-type layer. The Al composition ratio of the electron blocking layer is highest except for AIN buffer layer.

Since the ultraviolet light-emitting device is made of AlGaN that is more easily grown in a longitudinal direction than GaN, there is a problem such as deterioration in crystal quality or flatness. When a processed substrate having irregularities thereon is employed, the irregularities must be filled. To solve these problems, the Al composition ratio of each layer is preferably as low as possible. However, the structure of the ultraviolet light-emitting device disclosed in Japanese Patent Application Laid-Open (kokai) No. 2013-222746 leads to higher Al composition ratio of each layer.

### SUMMARY OF THE INVENTION

An object of the present invention is to improve crystallinity, flatness, and feasibility of filling in irregularities on the surface of the processed substrate in the Group III nitride semiconductor ultraviolet light-emitting device.

The present invention is a Group III nitride semiconductor ultraviolet light-emitting device comprising a substrate, a buffer layer disposed on the substrate and made of Group III nitride semiconductor containing Al, an undoped layer disposed on the buffer layer and made of undoped Group III nitride semiconductor, an n-type layer disposed on the undoped layer and made of n-type Group III nitride semiconductor containing Al, a light-emitting layer disposed on the n-type layer and made of Group III nitride semiconductor, which emits an ultraviolet ray, an electron blocking layer disposed on the light-emitting layer and made of p-type Group III nitride semiconductor containing Al, and a p-type contact layer disposed on the electron blocking layer and made of p-type Group III nitride semiconductor containing Al, wherein the bandgap energy of the undoped layer is the smallest of the next four layers and the bandgap energy is increased in the order of the undoped layer, the n-type layer, the p-type contact layer, and the electron blocking layer.

The ultraviolet light-emitting device of the present invention is a light-emitting device which emits ultraviolet ray having a wavelength of 210 nm to 400 nm. Specifically, the present invention is effective as a light-emitting device which emits UVA ray having a wavelength of 320 nm to 400 nm. As used herein, the term “emission wavelength” refers to a peak wavelength at the rated current or the current value actually used in the product.

When the undoped layer is formed of GaN or AlGaN, and the n-type layer, the electron blocking layer, and the p-type contact layer are formed of AlGaN, the Al composition ratio of the undoped layer is the lowest of the nest four layers, and the Al composition ratio is increased in the order of the undoped layer, the n-type layer, the p-type contact layer, and the electron blocking layer.

The present invention is suitable for the case where the substrate has irregularities on the surface at the buffer layer side to improve light extraction. The present invention facilitates flattening by filling in the irregularities. When the buffer layer is made of AIN, the filling in the irregularities is further facilitated.

When the emission wavelength is 365 nm or more, the undoped layer is formed of GaN, and when the emission wavelength is 365 nm or less, the undoped layer is formed of AlGaN. This is to reduce the loss due to self-absorption.

When the emission wavelength is 350 nm or longer to shorter than 370 nm, the Al composition ratio of the undoped layer is 3% to 6%, the Al composition ratio of the n-type layer is 6% to 10%, the Al composition ratio of the electron blocking layer is 37% to 50%, and the Al composition ratio of the p-type contact layer is 8% to 15%. Hereinafter, % refers to the mol % or atomic % to the total amount of Group III elements. Thereby, the crystal quality or flatness, and the feasibility of filling in irregularities can be further improved.

When the emission wavelength is 370 nm or longer to shorter than 390 nm, the Al composition ratio of the undoped layer is 0% to 2%, the Al composition ratio of the n-type layer is 1% to 4%, the Al composition ratio of the electron blocking layer is 29% to 40%, and the Al composition ratio of the p-type contact layer is 5% to 10%. Thereby, the crystal quality or flatness, and the feasibility of filling in irregularities can be further improved.

When the emission wavelength is shorter than 350 nm, the Al composition ratio of the undoped layer is 6% or more, the Al composition ratio of the n-type layer is 10% or more, the Al composition ratio of the electron blocking layer is 50% or more, and the Al composition ratio of the p-type contact layer is 15% or more. Thereby, the crystal quality or flatness, and the feasibility of filling in irregularities can be further improved.

The present invention is a method for producing a Group III nitride semiconductor ultraviolet light-emitting device, the method comprising forming an AIN buffer layer on a substrate having irregularities thereon by sputtering or PPD (Pulse Plasma Diffusion), forming a flat undoped layer on the buffer layer by growing an undoped Group III nitride semiconductor through low pressure MOCVD and filling in the irregularities on the substrate, forming an n-type layer made of n-type Group III nitride semiconductor having a bandgap energy larger than that of the undoped layer on the undoped layer through low pressure MOCVD, forming a Group III nitride semiconductor light-emitting layer on the n-type layer through low pressure MOCVD, forming an electron blocking layer made of p-type Group III nitride semiconductor having a bandgap energy larger than that of the n-type layer on the light-emitting layer through low pressure MOCVD, and forming a p-type contact layer made of p-type Group III nitride semiconductor having a bandgap energy larger than that of the n-type layer and having a bandgap energy smaller than that of the electron blocking layer on the electron blocking layer through low pressure MOCVD.

The present invention is also a method for producing a Group III nitride semiconductor ultraviolet light-emitting device, the method comprising forming an AIN buffer layer on a flat substrate by sputtering or PPD, forming an undoped GaN layer on the buffer layer through low pressure MOCVD, forming an n-type layer made of n-type Group III nitride semiconductor on the undoped layer through low pressure MOCVD, forming a Group III nitride semiconductor light-emitting layer on the n-type layer through low pressure MOCVD, forming an electron blocking layer made of p-type Group III nitride semiconductor having a bandgap energy larger than that of the n-type layer on the light-emitting layer through low pressure MOCVD, forming a p-type contact layer made of p-type Group III nitride semiconductor having a bandgap energy larger than that of the n-type layer and having a bandgap energy smaller than that of the electron blocking layer on the electron blocking layer through low pressure MOCVD, exposing the undoped layer by removing the substrate through laser lift-off, exposing the n-type layer by removing the undoped layer through wet etching from the exposed surface of the undoped layer and forming irregularities on the exposed surface of the n-type layer.

The present invention can reduce the Al composition ratio of the entire Group III nitride semiconductor ultraviolet light-emitting device, thereby improving the crystal quality, flatness, and feasibility of filling in the processed substrate.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a schematic view illustrating the structure of an ultraviolet light-emitting device according to Embodiment 1;

FIG. 2 is a schematic view illustrating a variation of the structure of the ultraviolet light-emitting device according to Embodiment 1;

FIGS. 3A and 3B are sketches showing processes for producing the ultraviolet light-emitting device according to Embodiment 1;

FIG. 4 is a schematic view illustrating the structure of an ultraviolet light-emitting device according to Embodiment 2; and

FIGS. 5A to 5D are sketches showing processes for producing the ultraviolet light-emitting device according to Embodiment 2.

### DETAILED DESCRIPTION OF PREFERRED EMBODIMENTS

Specific embodiments of the present invention will next be described with reference to the drawings. However, the present invention is not limited to the embodiments.

### Embodiment 1

FIG. 1 is a schematic view illustrating the structure of an ultraviolet light-emitting device according to Embodiment 1. As shown in FIG. 1, the ultraviolet light-emitting device according to Embodiment 1 includes a substrate 10; and an undoped layer 12, an n-type layer 13, a light-emitting layer 14, an electron blocking layer 15, and a p-type contact layer 16, which are sequentially deposited on the substrate 10 via a buffer layer 11. A trench extending from the surface of the p-type contact layer 16 to the n-type layer 13 is formed, and an n-electrode 18 is disposed on the n-type layer 13 exposed in the bottom of the trench. A p-electrode 17 is disposed on the p-type contact layer 16. The ultraviolet light-emitting device according to Embodiment 1 is a flip-chip type device which extracts light from the substrate 10 by reflecting a light emitted from the light-emitting layer 14 to the opposite side of the substrate 10 toward the substrate 10 by the p-electrode 17.

The substrate 10 is a sapphire substrate having a c-plane main surface, and a processed substrate having irregularities on one surface (surface at the buffer layer 11 side). The irregularities provided on one surface of the substrate 10 are projections arranged in a two-dimensional period. Having such irregularities on the surface of the substrate 10 improves light extraction.

Each of the projections has a shape of, for example, a pyramid, a cone, a truncated pyramid, a truncated cone, a prism, and a column. When the projection has a shape selected from a group consisting of a pyramid, a truncated pyramid and a prism, the shape of the bottom surface is preferably a regular polygon such as an equilateral triangle, a square, and a regular hexagon. The projections are arranged in, for example, square lattice, triangle lattice, and honeycomb pattern.

Although the height, width, and interval of the projection are arbitrary, they are preferably within a range of 0.1 μm to 10 μm. Light extraction can be sufficiently improved within this range, and the irregularities on substrate 10 can be flattened by filling with the undoped layer 12.

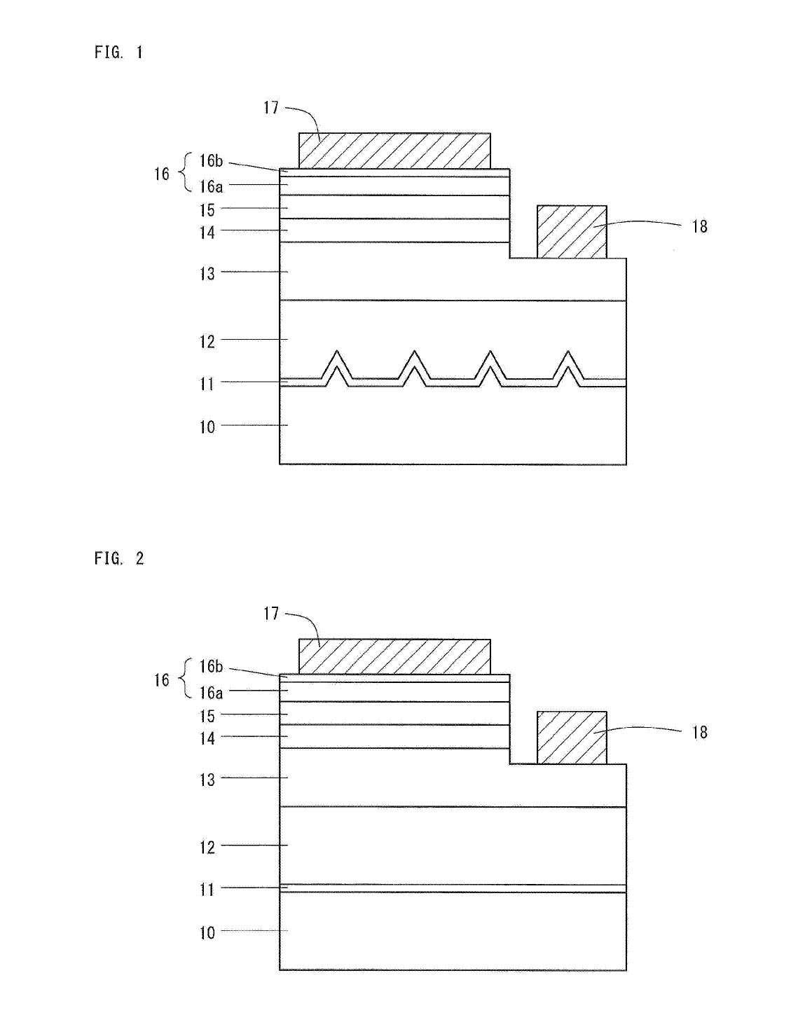

In Embodiment 1, a pattern in which projections are arranged is employed. On the contrary, a pattern in which recesses are reversely arranged or a stripe pattern may be employed. As shown in FIG. 2, a flat substrate having no irregularities thereon may be employed.

The substrate 10 may be formed of, other than sapphire, for example, Sa, SiC, SCAM (ScAlMgO₄), ZnO, TiO, and AlN.

The buffer layer 11 is disposed on the surface having irregularities of the substrate 10, and formed in a film state along the shape of irregularities thereon. The buffer layer 11 is formed of undoped AlN, and has a thickness of 5 nm to 20 nm. The buffer layer 11 is formed by sputtering or PPD (Pulse Plasma Diffusion).

The buffer layer 11 may also be formed of Group III nitride semiconductor containing Al such as AlGaN. However, the higher the Al composition ratio, the more the feasibility of filling in irregularities on the substrate 10, thereby further flattening the crystal surface. Therefore, the Al composition ratio of the buffer layer 11 is preferably as large as possible, and the Al composition ratio is, more preferably, 50% or more, and AlN is most preferable as in Embodiment 1.

The undoped layer 12 is disposed on the buffer layer 11, and the surface thereof (the surface opposite to the buffer layer 11 side) is flat. The undoped layer 12 reduces the dislocations in the crystal, and improves the crystal quality, thereby flattening the crystal surface by filling in the irregularities on the substrate 10.

The thickness of the undoped layer 12 is 0.5 μm to 10 μm. When the thickness is less than 0.5 μm, the reduction effect of the dislocation is not sufficient. When the thickness is more than 10 μm, it takes time to grow, causing a problem such as wafer warpage. The thickness is, more preferably, 1 μm to 5 μm, and, further preferably, 3 μm to 5 μm.

The undoped layer 12 is formed of undoped AlGaN. The Al composition ratio of the undoped layer 12 is constant in a thickness direction. The Al composition ratio of the undoped layer 12 is lower than the Al composition of the n-type layer 13, and not lower than the Al composition ratio at which an emitted light with the emission wavelength decided by a bandgap energy of the light-emitting layer 14 is not absorbed. For example, the emission wavelength is 320 nm to 365 nm, the Al composition ratio of the undoped layer 12 is 3% to 6%, which corresponds to 3.44 eV to 3.49 eV in bandgap energy. When the emission wavelength is 365 nm to 400 nm, the Al composition ratio is higher than 0% to not higher than 2%, which corresponds to 3.39 eV to 3.42 eV in bandgap energy.

When the peak wavelength of the emitted light is longer than 370 nm, the undoped layer 12 may be formed of GaN. When GaN is used as the undoped layer 12, the feasibility of filling in irregularities on the substrate 10 is better than that when the undoped layer contains Al, thereby improving crystallinity or surface flatness. Particularly, edge dislocation is reduced, thereby improving the crystallinity.

The Al composition ratio of the undoped layer 12 may not be constant in the thickness direction, and the Al composition may be continuously and gradually increased up to the value not higher than the Al composition ratio of the n-type layer 13. However, to reduce the dislocations in the crystal and improve the crystal quality, the Al composition ratio is preferably uniform in the thickness direction. When the Al composition ratio of the undoped layer 12 is continuously and gradually varied in the thickness direction, the average Al composition ratio in the thickness direction is lower than the Al composition ratio of the n-type layer 13.

A rough layer may be formed between the buffer layer 11 and the undoped layer 12. The rough layer is grown at a lower temperature at the initial growth stage of the undoped layer 12, and is a layer formed by crystal growing mainly facet planes on the buffer layer 11 (a layer grown via the buffer layer 11 on the side surfaces of the projections on the substrate 10). Such a rough layer prevents the concentration of dislocations, thereby improving the surface flatness as well as enhancing the crystal quality. The thickness of the rough layer is preferably 1 to 1.5 times the height of the projection in forming irregularities on the substrate 10. Within this range, the effect of preventing the concentration of dislocations can be sufficiently achieved. The thickness of the rough layer is, more preferably, 1.2 to 1.3 times the height of the projection in forming irregularities on the substrate 10.

The n-type layer 13 is disposed on the undoped layer 12. The n-type layer 13 is formed of Si-doped n-type AlGaN. The thickness of the n-type layer 13 is 0.5 μm to 3 μm. The Si concentration of the n-type layer 13 is 1×10¹⁸/cm³ to 1×10²⁰/cm³.

The Al composition ratio of the n-type layer 13 is higher than the Al composition ratio of the undoped layer 12, and lower than the Al composition ratio of the p-type contact layer 16. For example, when the emission wavelength is 320 nm to 365 nm, the Al composition ratio of the n-type layer 13 is 6% to 10%, which corresponds to 3.49 eV to 3.55 eV in bandgap energy. When the emission wavelength is 365 nm to 400 nm, the Al composition ratio of the n-type layer 13 is higher than 0% and not higher than 4%, which corresponds to 3.39 eV to 3.45 eV in bandgap energy.

The n-type layer 13 may have a plurality of layers. In that case, various structures conventionally known as the structure of the n-type layer in the Group III nitride semiconductor light-emitting device can be employed. In the n-type layer 13, the Si concentration may not be constant in the thickness direction, and may be continuously and gradually varied. For example, the Si concentration of the region in contact with the n-electrode 18 of the n-type layer 13 may be higher and the Si concentration of other region may be lower than the above. The Al composition ratio may be gradually or continuously varied in the thickness direction. However, to reduce the dislocations in the crystal and improve the crystal quality, the Al composition ratio is preferably uniform in the thickness direction. When the Al composition ratio of the n-type layer 13 is continuously and gradually varied, the average Al composition ratio in the thickness direction may be higher than the Al composition ratio of the undoped layer 12, and lower than the Al composition ratio of the p-type contact layer 16. Other impurities such as Mg in addition to Si may be co-doped to adjust the characteristics such as transmittance, within a range where the n-type layer shows the n-type conduction.

In the ultraviolet light-emitting device according to Embodiment 1, an n-type SL layer (superlattice layer) is not formed, which was formed between the n-type layer 13 and the light-emitting layer 14 in the conventional blue light-emitting device. This is because of the following reasons. In the blue light-emitting device, a lattice volume of the light-emitting layer 14 is larger than that of the n-type layer 13. To reduce the lattice mismatch and relax the stress applied to the light-emitting layer 14, an n-type SL layer (superlattice layer) was conventionally formed by repeatedly depositing InGaN and GaN. However, in the ultraviolet light-emitting device, the lattice volume of the light-emitting layer 14 is smaller than that of the n-type layer 13, and the stress is applied in the opposite direction to the light-emitting layer 14. Thus, there is almost no need for relaxing the stress applied to the light-emitting layer 14 by forming the n-type SL layer. In the ultraviolet light-emitting device according to Embodiment 1, an n-type SL layer is not formed between the n-type layer 13 and the light-emitting layer 14, thereby simplifying the structure. Needless to say, the structure having the n-type SL layer of AlGaN and GaN being repeatedly deposited may be employed.

The light-emitting layer 14 has a multiple quantum well (MQW) structure in which a well layer and a barrier layer are repeatedly deposited. The number of repetitions is 3 to 10. The barrier layer is made of AlGaN, and has a thickness of 2 nm to 15 nm. The well layer is made of a material selected according to a desired ultraviolet emission wavelength, and has a thickness of one molecular layer to 15 nm. Since the emission wavelength of GaN is 365 nm and the emission wavelength of AIN is 210 nm, to set the emission wavelength of the light-emitting layer 14 within a range of longer than 365 nm, the well layer is made of an InGaN based material, and the emission wavelength is adjusted by the In composition ratio. On the other hand, to set the emission wavelength of the light-emitting layer 14 within a range of 210 nm to shorter than 365 nm, the well layer is made of an AlGaN based material, and the emission wavelength is adjusted by the Al composition ratio. Needless to say, the well layer may be made of AlGaInN, and the emission wavelength may be adjusted by both the Al composition ratio and the In composition ratio.

In Embodiment 1, the light-emitting layer 14 has a MQW structure. However, it may have a SQW structure (single quantum well structure).

The electron blocking layer 15 is disposed on the light-emitting layer 14. The electron blocking layer 15 is an Mg-doped p-type AlGaN layer. The overflow of electrons from the light-emitting layer 14 to the p-type contact layer 16 is suppressed by forming the electron blocking layer 15 between the light-emitting layer 14 and the p-type contact layer 16. The Mg concentration of the electron blocking layer 15 is 1×10¹⁹/cm³ to 1×10²¹/cm³. The thickness of the electron blocking layer 15 is 1 nm to 50 nm.

The Al composition ratio of the electron blocking layer 15 is higher than those of the p-type contact layer 16 and the barrier layer of the light-emitting layer 14. For example, when the emission wavelength is 320 nm to 365 nm, the Al composition ratio of the electron blocking layer 15 is 37% to 50%, which corresponds to 4.13 eV to 4.47 eV in bandgap energy. When the emission wavelength is 365 nm to 400 nm, the Al composition ratio of the electron blocking layer 15 is 29% to 40%, which corresponds to 3.94 eV to 4.20 eV in bandgap energy. Under the conditions where the Mg concentration of the electron blocking layer 15 is within the above range, to sufficiently suppress the overflow of electrons by the electron blocking layer 15, the Al composition ratio of the electron blocking layer 15 is preferably higher by 10% or more than that of the barrier layer of the light-emitting layer 14.

The Mg concentration may not be constant in a thickness direction but may be continuously or gradually varied. The Al composition ratio may be gradually or continuously varied in the thickness direction. The electron blocking layer 15 may be doped with other impurities such as Si in addition to Mg to adjust the characteristics such as transmittance, within a range where the electron blocking layer shows the p-type conduction. The electron blocking layer 15 may comprise a single layer or a plurality of layers, e.g. a superlattice structure in which Group III nitride semiconductor layers having different composition ratios (such as AlGaN and GaN) are alternately and repeatedly deposited, to further improve the effect of suppressing the overflow of electrons.

The p-type contact layer 16 is disposed on the electron blocking layer 15. The p-type contact layer 16 has a two-layer structure in which a first p-type contact layer 16a made of Mg-doped p-type AlGaN and a second p-type contact layer 16b made of Mg-doped GaN are sequentially deposited on the electron blocking layer 15. The second p-type contact layer 16b being the surface layer in contact with the p-electrode 17 of the p-type contact layer 16 is made of GaN to reduce the contact resistance. Considering the absorption by the GaN layer, the thickness of the p-type contact layer 16b is preferably 20 nm or less.

The first p-type contact layer 16a has a thickness of 20 nm to 100 nm, and an Mg concentration of 1×10¹⁹/cm³ to 1×10²⁰/cm³. The second p-type contact layer 16b has a thickness of 2 nm to 10 nm, and an Mg concentration of 1×10²⁰/cm³ to 1×10²²/cm³.

The Al composition ratio (average in the thickness direction) of the p-type contact layer 16 is higher than the Al composition ratio of the n-type layer 13, and lower than the Al composition ratio of the electron blocking layer 15. For example, when the emission wavelength is 320 nm to 370 nm, the Al composition ratio of the p-type contact layer 16 is 8% to 15%, which corresponds to 3.52 eV to 3.65 eV in bandgap energy. When the emission wavelength is 365 nm to 400 nm, the Al composition ratio of the p-type contact layer 16 is 5% to 10%, which corresponds to 3.47 eV to 3.55 eV in bandgap energy.

The p-type contact layer 16 may comprise a single layer or a plurality of layers. In the case of multiple layer structure, it is not limited to the above structure, and conventional various multiple layer structures may be employed.

The Mg concentration of the p-type contact layer 16 may not be constant in the thickness direction but may be continuously or gradually varied. The Al composition ratio may be gradually or continuously varied in the thickness direction. The p-type contact layer 16 may be doped with impurities such as Mg in addition to Si to adjust the characteristics such as transmittance, within a range where the p-type contact layer 16 shows the p-type conduction.

Mg is difficult to enter the crystal at the initial stage of the crystal growth, and more difficult to enter the crystal the higher the Al composition ratio. In the electron blocking layer 15 or the p-type contact layer 16, to control the Mg concentration so as to be constant in the thickness direction, the Al composition ratio is decreased at the initial stage of the crystal growth to make Mg easy to enter the crystal, and then the Al composition ratio is increased to be constant.

The Al composition ratios of the undoped layer 12, the n-type layer 13, the electron blocking layer 15, and the p-type contact layer 16 have the following relationship. The Al composition ratios of the undoped layer 12, the n-type layer 13, the electron blocking layer 15, and the p-type contact layer 16 are respectively defined as x1, x2, x3, and x4. When the Al composition ratio is continuously or gradually varied in the thickness direction of each layer, x1, x2, x3, and x4 show an average of the Al composition ratios in each thickness direction. At this time, the Al composition ratio of each layer is set so as to satisfy the condition: x1<x2<x4<x3. Each layer having such an Al composition ratio can reduce the Al composition ratio of the entire ultraviolet light-emitting device, thereby improving the crystal quality, flatness, feasibility of filling in irregularities on the substrate 10.

Since the undoped layer 12 has the lowest Al composition ratio, i.e., the smallest bandgap energy of all layers, to reduce light loss due to self-absorption, the Al composition ratio of the undoped layer 12 may satisfy that the emission wavelength of the light-emitting layer 14 is not absorbed. When the emission wavelength is larger than 365 nm, the undoped layer 12 may be formed of GaN. GaN can improve the crystal quality, flatness, or feasibility of filling in irregularities on the substrate 10.

When the emission wavelength is 350 nm or longer to shorter than 370 nm, the Al composition ratio of each layer is preferably within the following range and x1<x2<x4<x3. The undoped layer 12 has an Al composition ratio x1 of 3% to 6%, the n-type layer 13 has an Al composition ratio x2 of 6% to 10%, the electron blocking layer 15 has an Al composition ratio x3 of 37% to 50%, and the p-type contact layer 16 has an Al composition ratio x4 of 8% to 15%. Such a range of Al composition ratio can further improve the crystal quality, flatness, or feasibility of filling in irregularities on the substrate 10.

When the emission wavelength is 370 nm or longer to shorter than 390 nm, the Al composition ratio of each layer is preferably within the following range and x1<x2<x4<x3. The undoped layer 12 has an Al composition ratio x1 of 0% to 2%, the n-type layer 13 has an Al composition ratio x2 of 1% to 4%, the electron blocking layer 15 has an Al composition ratio x3 of 29% to 40%, and the p-type contact layer 16 has an Al composition ratio x4 of 5% to 10%. Such a range of Al composition ratio can further improve the crystal quality, flatness, or feasibility of filling in irregularities on the substrate 10.

When the emission wavelength is shorter than 350 nm, the Al composition ratio of each layer is preferably as follows in the above range satisfying x1<x2<x4<x3. The undoped layer 12 has an Al composition ratio x1 of 6% or more, the n-type layer 13 has an Al composition ratio x2 of 10% or more, the electron blocking layer 15 has an Al composition ratio x3 of 50% or more, and the p-type contact layer 16 has an Al composition ratio x4 of 15% or more. Such a range of Al composition ratio can further improve the crystal quality, flatness, or feasibility of filling in irregularities.

Since the absorption wavelength of Group III nitride semiconductor can be adjusted by the concentration of impurities such as Mg or Si, light loss due to self-absorption may be reduced by doping with either or both of Mg and Si and adjusting the concentration.

In the above-mentioned ultraviolet light-emitting device according to Embodiment 1, the Al composition ratio is reduced as a whole, and the crystallinity and flatness are excellent. Even if irregularities are formed on a substrate 10 to improve light extraction, the surface can be flattened by filling in the irregularities.

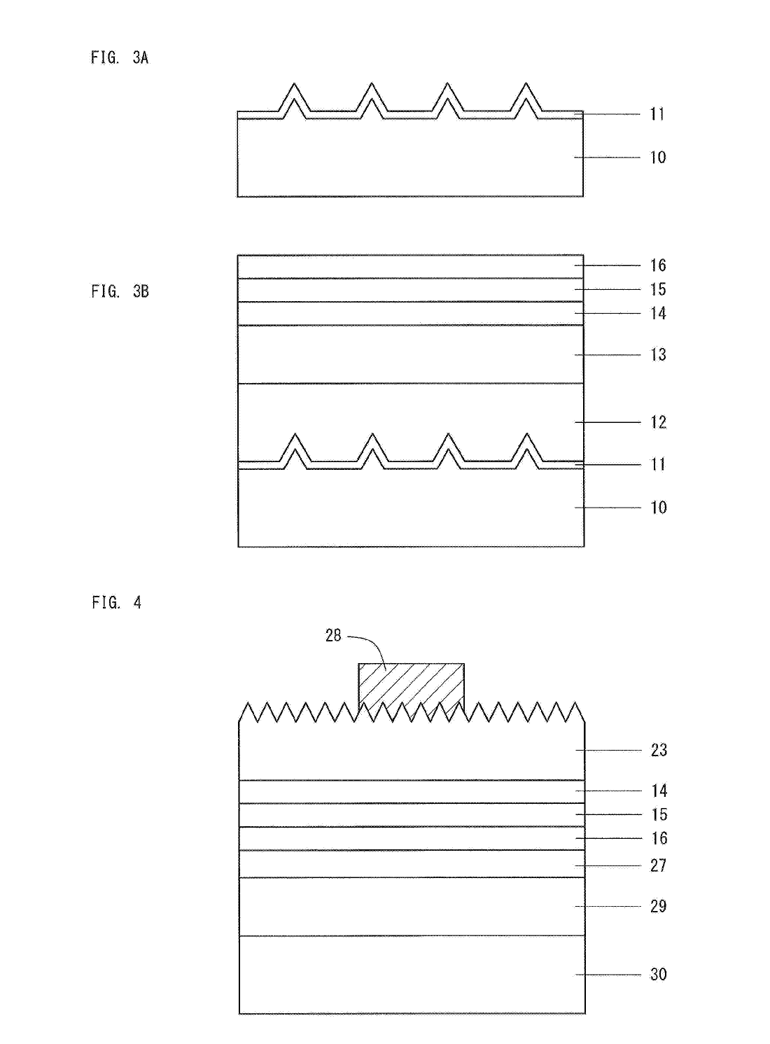

Next will be described processes for producing the ultraviolet light-emitting device according to Embodiment 1 with reference to FIGS. 3A and 3B.

Firstly, a substrate 10 having irregularities thereon is prepared. On the substrate 10, an AIN buffer layer 11 is formed by magnetron sputtering (FIG. 3A). Magnetron sputtering is performed with high purity metal aluminum as a target in a nitrogen gas atmosphere. The substrate temperature is 300° C. to 600° C., and the pressure is 1 Pa to 4 Pa. The buffer layer 11 is formed in a film along the irregularities on the substrate 10. A various types of sputtering including DC sputtering, RF sputtering, ion beam sputtering, and ECR sputtering may be employed other than magnetron sputtering. Other than sputtering, PPD (Pulse Plasma Diffusion) may be employed to form a buffer layer 11. In that case, before the formation of the buffer layer 11, the substrate 10 may be heated to a temperature of 800° C. to 1100° C. at a normal pressure and under hydrogen or nitrogen atmosphere to remove impurities adhered on the surface of the substrate.

Subsequently, an undoped layer 12, an n-type layer 13, a light-emitting layer 14, an electron blocking layer 15, and a p-type contact layer 16 are sequentially formed on the buffer layer 11 through low pressure MOCVD (FIG. 3B). The pressure is 0.05 atm to 0.5 atm, and the growth temperature is 1100° C. to 1200° C. When a rough layer is formed between the buffer layer 11 and the undoped layer 12, the initial growth temperature of the undoped layer 12 is a low temperature of 950° C. to 1080° C., and thereafter may be increased up to a predetermined growth temperature.

The raw material gases employed in MOCVD is trimethylgallium as a Ga source, trimethylaluminum as an Al source, trimethylindium as an In source, ammonia as nitrogen source, bis(cyclopentadienyl)magnesium as a p-type dopant gas, and silane as an n-type dopant gas. The carrier gas employed in the method is usually hydrogen (H₂). Only when a layer containing In is formed, nitrogen was employed as a carrier gas.

The buffer layer 11 is made of AlN formed by sputtering, and the undoped layer 12 is formed of AlGaN having an Al composition ratio lower than that of the n-type layer 13, under reduced pressure. Therefore, irregularities on the substrate 10 are effectively filled in by the undoped layer 12, thereby flattening the surface.

Next, a part of the surface of the p-type contact layer 16 is subjected to dry etching, and a trench is formed so as to expose the n-type layer 13 in the bottom surface. A p-electrode 17 is formed on the surface of the p-type contact layer 16, and an n-electrode 18 is formed on the n-type layer 13 exposed in the bottom surface of the trench. Thus, the ultraviolet light-emitting device according to Embodiment 1, as shown in FIG. 1, is produced.

The ultraviolet light-emitting device according to Embodiment 1 produced as described above, has good filling properties of irregularities on the substrate 10 and a low threading dislocation density of 1×10⁸/cm² or less, thereby easily obtaining a flat surface because the buffer layer 11 is formed by sputtering, and the undoped layer 12 is formed through low pressure MOCVD.

### Embodiment 2

FIG. 4 is a schematic view illustrating the structure of an ultraviolet light-emitting device according to Embodiment 2. As shown in FIG. 4, the ultraviolet light-emitting device according to Embodiment 2 comprises a support substrate 30, a bonding layer 29 disposed on the support substrate 30, a p-electrode 27 disposed on the bonding layer 29, a p-type contact layer 16 disposed on the p-electrode 27, an electron blocking layer 15 disposed on the p-type contact layer 16, a light-emitting layer 14 disposed on the electron blocking layer 15, an n-type layer 23 disposed on the light-emitting layer 14, and an n-electrode 28 disposed on the n-type layer 23. The ultraviolet light-emitting device according to Embodiment 2 has a structure in which a growth substrate is removed, and an electric conduction is obtained in a longitudinal direction.

The light-emitting layer 14, the electron blocking layer 15, and the p-type contact layer 16 have the same structure as those of the ultraviolet light-emitting device according to Embodiment 1. The n-type layer 23 has the same structure as that of the n-type layer 13 of the ultraviolet light-emitting device according to Embodiment 1 except that the entire surface at the opposite side of the light-emitting layer 14 is exposed, and irregularities are provided. The Al composition ratios of the n-type layer 23, the electron blocking layer 15, and the p-type contact layer 16 are respectively defined as x2, x3, and x4. The Al composition ratio x2 of the n-type layer 23 is the smallest of the next three layers, and the Al composition ratio is increased in the order of the n-type layer 23, the p-type contact layer 16, and the electron blocking layer 15. That is, x2<x4<x3. The bonding layer 29 is a metal layer to bond the p-electrode 27 and the support substrate 30.

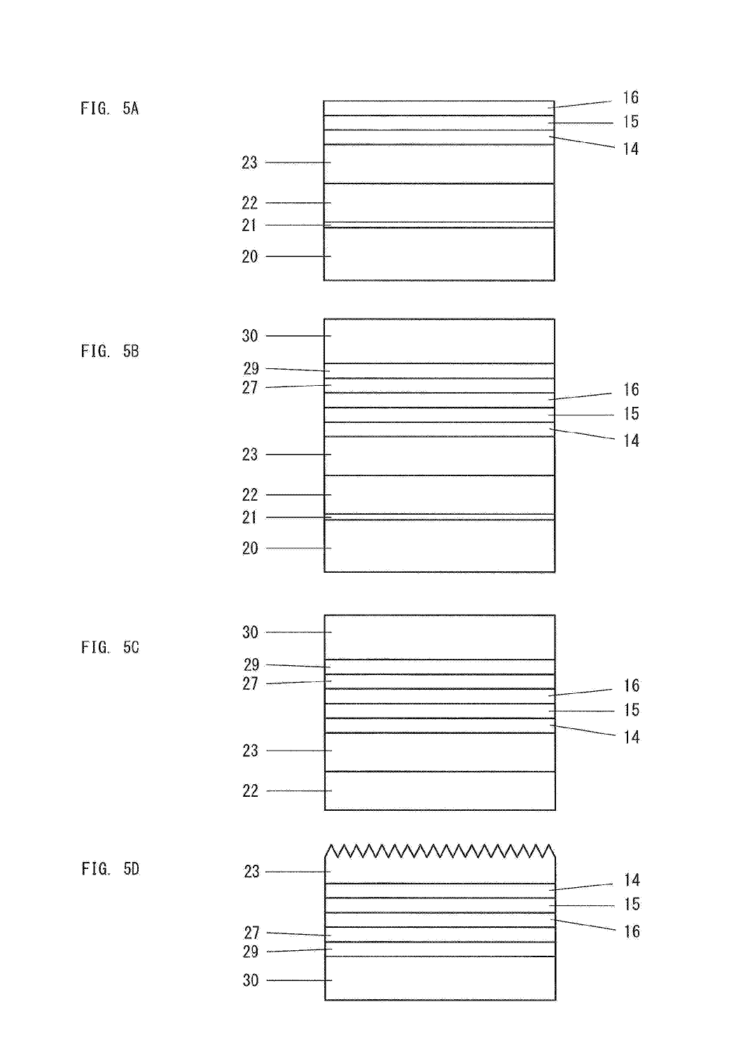

Next will be described processes for producing the ultraviolet light-emitting device according to Embodiment 2 with reference to FIGS. 5A to 5D.

Firstly, a flat substrate 20 for crystal growth is prepared. The substrate 20 may be made of the same material as that of the substrate 10 of the ultraviolet light-emitting device according to Embodiment 1. Same as the buffer layer 11 of Embodiment 1, an AlN buffer layer 21 is formed on the substrate 20 by sputtering. When the buffer layer 21 is formed by PPD (Pulse Plasma Diffusion) instead of sputtering, the substrate 20 may be heated to a temperature of 800° C. to 1100° C. at a normal (atmospheric) pressure under a hydrogen or nitrogen atmosphere to remove impurities adhered to the surface before the formation of the buffer layer 21.

Subsequently, in the same way as Embodiment 1, an undoped layer 22, an n-type layer 23, a light-emitting layer 14, an electron blocking layer 15, a p-type contact layer 16 are sequentially formed on the buffer layer 21 through low pressure MOCVD (FIG. 5A). The undoped layer 22 is made of undoped GaN which does not contain Al or impurities, thereby improving the crystal quality or flatness.

Next, a p-electrode 27 is formed on the p-type contact layer 16 by vapor deposition or sputtering, and is bonded to the support substrate 30 via the bonding layer 29 (FIG. 5B).

Subsequently, the buffer layer 21 and the substrate 20 are removed by laser lift-off (FIG. 5C). That is, by irradiating a laser with a predetermined wavelength from the rear surface of the substrate 20 (the surface opposite to the surface on which the buffer layer 21 was formed), the undoped layer 22 is decomposed and peeled off at an interface between the buffer layer 21 and the undoped layer 22, thereby separating and removing the substrate 20.

A various types of growth substrate removal methods conventionally known such as chemical lift-off may be employed other than laser lift-off.

Next, the undoped layer 22 is entirely removed by wet etching from the exposed surface of the undoped layer 22. The surface of the n-type layer 23 is etched to form irregularities (FIG. 5D). The surface of the undoped layer 22 exposed by laser lift-off is the nitrogen polarity plane of Group III nitride semiconductor, and can be wet-etched in alkaline solution such as TMAH, KOH, or phosphoric acid. Such wet etching has anisotropy, and irregularities can be formed on the n-type layer 23 due to anisotropy. These irregularities improve light extraction efficiency.

Subsequently, an n-electrode 28 is formed on the n-type layer 23 having irregularities through vapor deposition or sputtering. Thus, the ultraviolet light-emitting device according to Embodiment 2, as shown in FIG. 4, is produced.

In the above-mentioned production method for ultraviolet light-emitting device according to Embodiment 2, the buffer layer 21 is made of AIN formed by sputtering, the undoped layer 22 is made of GaN, and the Al composition ratio of the n-type layer 23 is the smallest of the next three layers, and the Al composition ratio is increased in the order of the n-type layer 23, the p-type contact layer 16, and the electron blocking layer 15, thereby improving the crystal quality or flatness. However, when the undoped layer 22 is made of GaN, ultraviolet ray is absorbed. Therefore, after the substrate 20 was removed through laser lift-off, the undoped layer 22 is removed by wet etching to reduce the loss due to self-absorption. In Embodiment 2, the crystal quality or flatness is high because Group III nitride semiconductor is crystal grown on the flat substrate 20.

When the emission wavelength is within a range of longer than 370 nm, no self-absorption occurs even if the undoped layer 22 is made of GaN. Therefore, the undoped layer 22 may not be entirely removed after laser lift-off.

### [Variations]

In Embodiment 1, the Al composition ratio of the undoped layer 12 is the smallest of the next four layers and the Al composition ratio is increased in the order of the undoped layer 12, the n-type layer 13, the p-type contact layer 16, and the electron blocking layer 15. That is, x1<x2<x4<x3. In Embodiment 2, the Al composition ratio of the n-type layer 23 is the smallest of the next three layers, and the Al composition ratio is increased in the order of the n-type layer 23, the p-type contact layer 16, and the electron blocking layer 15. That is, x2<x4<x3. The bandgap energy of the respective layers is increased in this order. In that case, the n-type layers 13 and 23, the electron blocking layer 15, and the p-type contact layer 16 may be made of Group III nitride semiconductor having any composition ratio containing Al, and the undoped layer 12 may be made of any Group III nitride semiconductor. Needless to say, the composition ratio with no self-absorption is preferably selected.

The ultraviolet light-emitting device of Embodiment 1 is of a flip chip type. However, alternatively, the present invention may also be applied to a face-up type ultraviolet light-emitting device.

The ultraviolet light-emitting device of the present invention is effective particularly as a UVA-LED having an emission wavelength of 320 nm to 400 nm.

The ultraviolet light-emitting device of the present invention may be employed for various usages such as sterilization, illumination, and resin curing.

What is claimed is:

1. A Group III nitride semiconductor ultraviolet light-emitting device comprising:
a substrate;
a buffer layer disposed on the substrate and made of Group III nitride semiconductor containing Al;
an undoped layer disposed on the buffer layer and made of undoped Group III nitride semiconductor;
an n-type layer disposed on the undoped layer and made of n-type Group III nitride semiconductor containing Al;
a light-emitting layer disposed on the n-type layer and made of Group III nitride semiconductor;
an electron blocking layer disposed on the light-emitting layer and made of p-type Group III nitride semiconductor containing Al; and
a p-type contact layer disposed on the electron blocking layer and made of p-type Group III nitride semiconductor containing Al;
wherein a bandgap energy of the undoped layer is the smallest of next four layers, and the bandgap energy is increased in an order of the undoped layer, the n-type layer, the p-type contact layer, and the electron blocking layer.

2. The ultraviolet light-emitting device according to claim 1,
wherein the undoped layer is made of at least one of GaN and AlGaN, wherein each of the n-type layer, the electron blocking layer, and the p-type contact layer is made AlGaN, respectively and
wherein the Al composition ratio of the undoped layer is the smallest of next four layers, and the Al composition ratio is increased in the order of the undoped layer, the n-type layer, the p-type contact layer, and the electron blocking layer.

3. The ultraviolet light-emitting device according to claim 2,
wherein the emission wavelength is 350 nm or longer to shorter than 370 nm, and
wherein the undoped layer has an Al composition ratio of 3% to 6%, the n-type layer has an Al composition ratio of 6% to 10%, the electron blocking layer has an Al composition ratio of 37% to 50%, and the p-type contact layer has an Al composition ratio of 8% to 15%.

4. The ultraviolet light-emitting device according to claim 2,
wherein the emission wavelength is 370 nm or longer to shorter than 390 nm, and
wherein the undoped layer has an Al composition ratio of 0% to 2%, the n-type layer has an Al composition ratio of 1% to 4%, the electron blocking layer has an Al composition ratio of 29% to 40%, and the p-type contact layer has an Al composition ratio of 5% to 10%.

5. The ultraviolet light-emitting device according to claim 2,
wherein the emission wavelength is shorter than 350 nm, and
wherein the undoped layer has an Al composition ratio of 6% or more, the n-type layer has an Al composition ratio or 10% or more, the electron blocking layer has an Al composition ratio of 50% or more, and the p-type contact layer has an Al composition ratio of 15% or more.

6. The ultraviolet light-emitting device according to claim 1, wherein the surface at the buffer layer side of the substrate comprises irregularities.

7. The ultraviolet light-emitting device according to claim 1, wherein the buffer layer consists of AIN.

8. A method for producing a Group III nitride semiconductor ultraviolet light-emitting device, the method comprising:
forming an AIN buffer layer on a substrate having irregularities by at least one of sputtering and Pulse Plasma Diffusion;
forming a flat undoped layer on the buffer layer by growing an undoped Group III nitride semiconductor through low pressure MOCVD and filling in the irregularities on the substrate;
forming an n-type layer made of n-type Group III nitride semiconductor having a bandgap energy larger than a bandgap energy of the undoped layer on the undoped layer through low pressure MOCVD;
forming a Group III nitride semiconductor light-emitting layer on the n-type layer through low pressure MOCVD;
forming an electron blocking layer made of p-type Group III nitride semiconductor having a bandgap energy larger than a bandgap energy of the n-type layer on the light-emitting layer through low pressure MOCVD; and
forming a p-type contact layer made of p-type Group III nitride semiconductor having a bandgap energy larger a bandgap energy of the n-type layer and having a bandgap energy smaller than a bandgap energy of the electron blocking layer on the electron blocking layer through low pressure MOCVD.

9. A method for producing a Group III nitride semiconductor ultraviolet light-emitting device, the method comprising:
forming an AIN buffer layer on a flat substrate by at least one of sputtering and Pulse Plasma Diffusion;
forming an undoped GaN layer on the buffer layer through low pressure MOCVD;
forming an n-type layer made of n-type Group III nitride semiconductor on the undoped layer through low pressure MOCVD;
forming a Group III nitride semiconductor light-emitting layer on the n-type layer through low pressure MOCVD;
forming an electron blocking layer made of p-type Group III nitride semiconductor having a bandgap energy larger than a bandgap energy of the n-type layer on the light-emitting layer through low pressure MOCVD;
forming a p-type contact layer made of p-type Group III nitride semiconductor having a bandgap energy larger than a bandgap energy of the n-type layer and having a bandgap energy smaller than a bandgap energy of the electron blocking layer on the electron blocking layer through low pressure MOCVD;
exposing the undoped layer by removing the substrate through laser lift-off;
exposing the n-type layer by removing the undoped layer through wet etching from the exposed surface of the undoped layer and forming irregularities on the exposed surface of the n-type layer.
